(19) United States
(12) Patent Application Publication
(10) Pub. No.: US 2003/0218865 A1
(43) Pub. Date: Nov. 27, 2003

(54) Semiconductor thermal management system

(76) Inventor: Jose Javier Macias, Grand Prairie, TX (US)

Correspondence Address: LARRY MASON LEE, 4408 SPICE WOOD SPRINGS RD., AUSTIN, TX, 78759, US

(21) Appl. No.: 10/154,724

(22) Filed: May 24, 2002

(51) Int. Cl. H05K 7/20

(52) U.S. Cl. 361/700; 62/3.3; 165/104.33

(57) ABSTRACT

A Thermal Management System adapted to meet current dimensional standards and providing direct Thermoelectric controlled temperatures to maintain semiconductor performance. The disclosed invention utilizes Thermoelectric Cooling Devices, a controller unit, both fluid and gaseous heat exchangers together with low cost construction methods to provide a compact, effective semiconductor Thermal Management System meeting the cooling needs of current and future high-speed, heat-producing semiconductors.

### BACKGROUND OF THE INVENTION

a. Field of the Invention

The present invention is related generally to the field of devices and systems that provide temperature control of semiconductors during operation.

The present invention is related more specifically to the field of devices and systems that utilize Peltier Effect Thermoelectric Coolers to provide temperature control of semiconductors during operation.

The present invention is related with yet further particularity to devices and systems that utilize Peltier Effect Thermoelectric Coolers in combination with Liquid Accumulators, Heat Exchangers, Liquid Tanks and Liquid Pumps to provide temperature control of semiconductors during operation.

b. Description of the Prior Art

The prior art in semiconductor temperature regulation systems utilize fans to cool the semiconductor. The instant invention does not utilize fans to cool the semiconductor, whereas it is standard and common in liquid Device designs, and, which are reliant on liquid and or air flow fans to cool semiconductors.

During the operation of a semiconductor its heat must be quickly carried away keeping the temperature of the semiconductor within or below its designed working temperature range. To maintain a semiconductor's temperature efficiently, extend the semiconductor's operational lifetime, and maximize the semiconductor's operational designed efficiencies, various semiconductor temperature control methods and devices have been disclosed in the prior art, including Thermoelectric Device arrangements. The instant invention provides a Thermoelectric Device in heat conductive contact with the semiconductor to be cooled and attached to the open area inside the Thermal Management System (TMS) base floor, and, in the preferred embodiment, a Liquid Accumulator which functions as a conductive solid to liquid heat exchanger that is inserted on top of and in heat conductive communication with the Thermoelectric Device.

### SUMMARY OF THE INVENTION

The instant invention, the Semiconductor Thermal Management System, utilizes TEC Devices to control semiconductor temperatures, and, utilizes a Liquid Accumulator to cool the hot side of a thermoelectric Device (TEC), for heat dissipation. The Thermal Management System's method of cooling a semiconductor is active TECs. The design of the instant invention also provides a safety-configuration and a heat dissipater to protect semiconductors from immediate heat failure if any part of the total TMS is impaired. A controller unit alerts the operator to shut down when temperatures reach a critical stage thus saving the semiconductor from immediate destruction.

Accordingly, it is an object of the present invention to provide for cooling of a semiconductor with Thermoelectric Devices, including a Liquid Accumulator, Pump and Heat Exchanger system in a closed end loop design.

Further, it is an object of the present invention to provide nonconductive Anchors 35 attached to the motherboard 1, which Anchors 35 are a universal support for the Thermal Management Systems attachment to the motherboard 1 by screws, which eliminates potential attachment and removal problems usually confronted when installing semiconductor cooling devices having a clip-on attachment system. The typical clip-on attachment system provides for clipping-on to the semiconductor housing itself, some clip-on attachment systems clip-on to the vanes of the heat sink surrounding and installed with the semiconductor.

Yet further, it is an object of the present invention to provide a: thermal management solution method for semiconductors, which thermal management solution method uses active Thermoelectric Devices, uses liquid as a heat transfer medium for cooling efficiencies, and which effectively and quickly carries heat away from the semiconductor.

Yet further, it is an object of the present invention to provide a Liquid Accumulator to cool the TEC devices hot side for controlled heat dissipation, while the Thermoelectric device's cold side cools the semiconductor to maintain and control the semiconductor's operational safe standards.

Yet further, it is an object of the present invention to provide an operational support method, such that, if a part or component of the Thermal Management System fails, the semiconductor continues to function at safe temperature levels and the operator is alerted when the semiconductors heat rises to a non-safe temperature zone and a control card turns off the semiconductor or electronic device, thus saving the semiconductor or electronic device from immediate failure.

Yet further and finally, it is an object of the present invention to provide a direct Thermoelectric Device method for the semiconductor cooling which is a direct spot cooling device by the TEC and that is adaptable to smaller environments requiring less installation space and can be simply produced through low cost manufacturing techniques.

### Description of Numeric References

1. Motherboard

2. Semiconductor

3. Thermal Management System frame

4. Liquid line from Liquid Accumulator to Heat Exchanger

5. Liquid line from Liquid Accumulator to Pump

6. Temperature probe

7. Electrical communication from temperature probe to controller card

8. Controller card

9. Electrical communication from Controller card to Pump

10. Pump

11. Liquid line from Heat Exchanger to Pump

12. Heat Exchanger

13. Fan

18. fluid fitting

23. fluid fitting

30. Top cover plate

31. Liquid Accumulator

35. Anchor

37. Heat probe aperture

40. Thermal Electric Device

41a-d. Screw Holes

42. Thermal Management System base floor

### BRIEF DESCRIPTION OF THE DRAWINGS

While the novel features of the instant invention are set forth with particularity in the appended claims, a fill and complete understanding of the invention can be had by referring to the detailed description of the preferred embodiment(s) which are set forth subsequently, and which are as illustrated in the accompanying drawings, in which:

FIG. 1 is a Block Diagram of the Thermal Management System component arrangement.

FIG. 2a is an inverted vertical plane view of the Thermal Management System frame.

FIG. 2b is a horizontal plane view of the Thermal Management System frame.

FIG. 2c is a horizontal plane view of the Thermal Management System frame.

FIG. 3 is vertical plane view of the Thermal Management System frame with Liquid Accumulator and Thermoelectric Device installed.

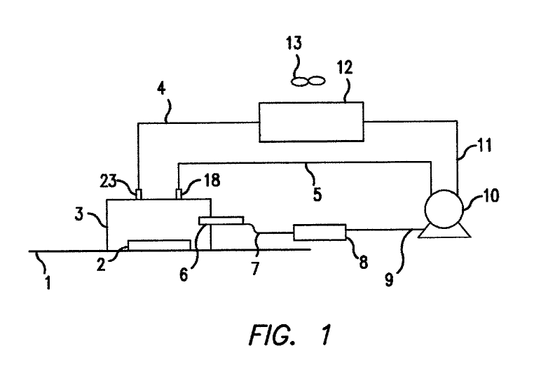

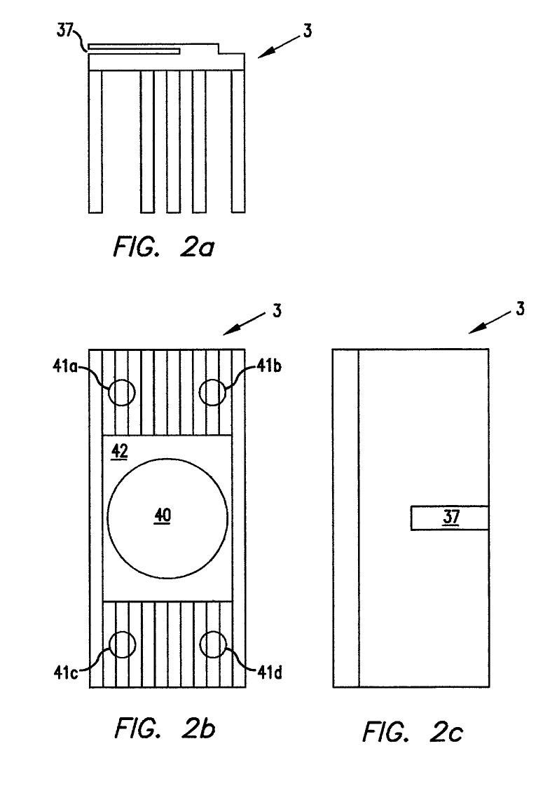

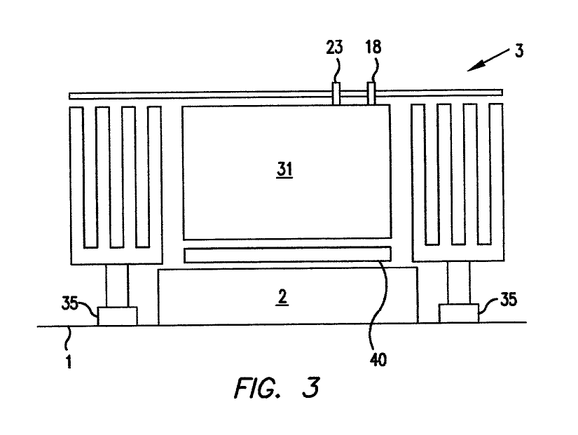

### DESCRIPTION OF THE PREFERRED EMBODIMENT(S)

The instant invention is a thermal control system that provides temperature control of a semiconductor 2 or other electronic device and utilizes Thermoelectric Coolers (TECs) 40 which are solid state heat pumps that utilize the Peltier Effect. The Thermal Management System (TMS) is a combination of direct active Thermoelectric Devices (TEC'S) 40 for temperature control of semiconductors 2, and includes Liquid Accumulators 31, Heat Exchangers 12, Liquid Tanks (not depicted in the drawings) and Liquid Pumps 10.

The Thermal Management System includes a Liquid Accumulator 31 and Thermoelectric devices (TEC's) 40 placed between the bottom of the Liquid Accumulator 31 and the bottom inside floor 42 of the Thermal Management System, which is attached to Anchors 35 in the area of the semiconductor's socket. The Thermoelectric Devices (TEC's) 40 provide direct and active cooling of semiconductors 2, with the additional heat exchange provided by the TMS frame 3. The TEC Device's 40 hot side heat is absorbed by the Liquid Accumulator 31 and the liquid passing through the Liquid Accumulator 31 including residual heat absorbed through the totality of the Thermal Management System. The TMS stabilizes the temperature of a semiconductor 2 or other electronic device and maintains the temperature within acceptable operational standards.

The Thermal Management System may be adapted to add or remove heat from a Thermoelectric Device 40, through differing configurations of the instant invention, and transfer such heat to the Liquid Accumulator 31 and to the Thermal Management System heat absorbing Frame 3. The Thermal Management System frame 3 design allows for the walls of the Liquid Accumulator's 31 exterior to be in heat conductive communication with the parallel side walls of the Thermal Management System's interior frame 3 and with the TMS's interior floor 42. The frame's 3 open interior area is designed to allow insertion of the Liquid Accumulator 31, which is placed on top of the TEC Device's 40 hot side to absorb the heat, and the TEC Device's 40 cold side is placed facing down and on top of the frame's interior floor 42. The combination of the TMS frame 3, with the TEC Device 40 placed on the frame's 3 interior floor 42 and the Liquid Accumulator 31 inserted into the frame 3 on top of the TEC Device 40 is placed directly over the semiconductor 2 which is emitting heat. The Liquid Accumulator 31 provides a liquid input fitting 18 and a liquid output fitting 23, liquid flow is though a liquid pump 10 and a liquid tank (not depicted in the drawings) with liquid tubes or lines 4 that connect to a liquid to air heat exchanger 12 with fans 13 to cool the liquid which is rotated back though the Thermal Management System to the Liquid Accumulator 31 through line 5 in a closed end loop design.

A second embodiment of the Thermal Management System provides for positioning of the TMS frame 3 such that it is in a contiguous contact with the Liquid Accumulator 31, and next to the parallel walls of the interior of the Thermal Management System's frame 3 which provides a recessed portion formed for receiving the Liquid Accumulator 31 therein and to fit within the Thermal Management System frame 3 and peripheral side walls.

The Liquid Accumulator's 31 interior design includes extensions protruding upwards from the base floor 42 beneath the Liquid Accumulator 31 to the top cover plate 30. The extensions are densely designed to efficiently transfer heat from the hot side of the thermoelectric Device 40 to the liquid within the Liquid Accumulator 31. The Liquid Accumulator 31 is positioned, when in use, adjacent to the parallel walls of the TMS frame's 3 interior and attached to the base or floor 42 of the TMS frame 3. The design of the internal extensions allow dense contact of the liquid for maximum heat transfer from the hot side of the TEC 40 to the liquid within the Liquid Accumulator 31.

A Thermoelectric Device 40 is mounted on the Thermal Management System (TMS) frame's 3 interior floor 42 and is located, when so mounted, in between the Liquid Accumulator's 31 bottom side and the top of the TMS frame 3 interior floor 42. This mounted location transfers heat through the heat conductive material of the TMS frame 3 interior floor 42 from the top, or hot side, of the Thermoelectric Device 40 to the bottom of the heat conductive Liquid Accumulator 31 and to the TMS heat conductive frame 3 generally. The TMS frame 3 interior floor 42 is made, in the preferred embodiment, of a thin sheet of copper.

The Thermal Management System's top cover plate 30 permits the TMS to receive screws inserted into screw holes, 41a-d, in the top cover plate 30. Such received screws insert down through the frame 3 of the TMS and into Anchors 35 attached to the motherboard 1. The Anchors 35 are made of high density non-conductive material. The top cover plate 30 of the TMS frame 3 has four-corners including four screw holes 41a-d, and the screw holes 41a-d permit the insertion of attachment screws that support and hold all four sides of the Thermal Management System frame 3 to the motherboard's 1 Anchors 35. The Anchors 35 are installed and positioned around the semiconductors 2 socket. The attachment screws are inserted into and through the TMS top plate 30 and pass through and into the TMS frame 3, and into the Anchors 35 attached to the motherboard 1.

The preferred embodiments design permits a specific attachment screw length which is pre-determined and the attachment screw is screwed down to a precise pressure, in pounds per inch, as required by motherboard 1 and semiconductor 2 manufacturer's specifications, and TEC 40 manufacturers specifications in order to conform to their recommended and safely applied contact pressures The TMS's top cover plate 30 permits connection of the TMS frame 3 with installed Liquid Accumulator 31 and TEC Device 40 to the motherboard 1. With equally distributed pressure as between the attachment screws the TMS frame's 3 movement can be avoided when the TMS frame 3 is attached over the semiconductor's 2 allowed attachment area. Further, with equally applied downward pressure provided by the attachment screws, the manufacturer's recommended pressure contact can be met over the entire surface of the semiconductor 2 being cooled.

The TMS top cover plate 30 contains four screw holes 41a-d, one in each corner of the four-sided plate. The plate supports and attaches the Thermal Management System frame 3 to the motherboard 1 without standard clip-on braces for attachment. The holes 41a-d in the top cover plate 30 allow insertion of four screws that pass through the top cover plate 30 openings and through the floor 42 of the TMS frame 3, and into the holes of the Anchor 35 allowing the TMS frame's 3 attachment to the motherboard 1.

Anchors 35 consist of nonconductive maternal that are attached to the motherboard 1 around the outside area of the semiconductor 2 socket configuration. The Anchors 35 have four holes each. Each hole conforms in diameter and spacing to the standard holes contained in the motherboards 1. The two adjacent holes in the Anchors 35 allow two screws for each Anchor 35 to attach the entire TMS frame 3 to Anchors 35 attached to the motherboard 1, which, when installed, places the TMS frame 3 over the socket for the semiconductor 2. Screws inserted into the holes of the Anchors 35 may be further secured with or by application of an expander material. Screw expanders provide additional outward pressure to the side walls of the screw holes, securing the screws to the Anchor 35 without causing damage to the motherboard 1 and are pressure specific for safety. The Anchors 35 do not interfere with the motherboard's 1 semiconductor's 2 socket area.

The four screws that pass through the TMS top cover plate 30 and through the bottom of the TMS frame 3 are predetermined in length and are tightened to the specific pounds per square inch of pressure allowed by motherboard 1 manufacturers for safety and effective contact. The length of each screw is, in the preferred embodiment, limited by the specific amount of pressure per screw turn that can be applied to the motherboard 1 when attaching the Thermal Management System frame 3 on top of the central processing unit's, or other semiconductor 2 or electronic device's, socket unit. The four screws do not, in the preferred embodiment, pass through the motherboard 1 Anchor 35; but may in other embodiments pass through the Anchor 35 into the motherboard 1.

A Temperature probe 6 insertion area 37 in the preferred embodiment of the Thermal Management System consists of a precut slot 37 in the base of the TMS frame 3. The temperature probe 6 opening 37 in the TMS frame 3 allows the insertion of a temperature probe 6 into the cut-out area 37. The temperature probe 6 is capable of measuring the semiconductor's 2 temperature accurately, communicating (through line 7) the temperature information to the controller card 8 which in turn communicates 9 a control signal to the pump 10, and is affordable low cost technology.

Anchors 35 attached to the motherboard 1 are a part of the preferred embodiment and the Anchors 35 are made of a non-conductive material. The Anchors 35 create a universal attachment platform for the quick, easy replacement of a large variety of semiconductor 2 cooling Devices without removing the motherboard. Current designs of semiconductor 2 cooling devices require the removal of the motherboard 1 to replace the cooling device which generally is equipped with clip-on attachment mechanism.

The present invention relates to Thermoelectric cooling of a semiconductor 2 arrangement and more specifically to a Liquid Accumulator 31, Pump 10 and Heat Exchanger system 12 for a thermal management solution arrangement for a semiconductor 2. The present invention also provides a universal Anchor 35 attachment method and, for the connection or removal from the motherboard 1 for changing a cooling attachment. The instant invention provides a temperature safety zone for the semiconductor 2 to continue to be operational if the said parts fail. The thermal heat from the semiconductor 2 is absorbed through the TMS frame 3, and prevents the semiconductor 2 from rising temperature failure levels that cause its immediate failure. The instant invention's properties sustain the semiconductor's 2 safe operational temperatures through conduction if all systems fail, and alerting the operator through a control card 8 design to shut down the semiconductor 2.

The Liquid Accumulator 31 is closely attached to the open area inside the TMS frame 3, and is adapted to cool the hot side of a thermoelectric device 40. Heat from the hot side of the Thermoelectric device 40 is absorbed into the Liquid Accumulator 31, and into the TMS frame 3, wherein said elevated temperatures are quickly dissipated. The TEC device's 40 cold side actively spot cools the semiconductor 2 through the TMS frame 3.

The Liquid Accumulator 31 has a liquid input fitting 18 connected to a liquid input tube and a liquid output fitting 23 connected to a liquid output tube. The liquid input tube 5 (name-designated in relation to the Liquid Accumulator 31) and the liquid output tube 4 are respectively connected to output and input ends of liquid pumping 10 and temperatures exchanging 12 units. The liquid pump 10 in the preferred embodiment is an inexpensive inline impeller unit and the temperatures exchanging unit is a simple liquid to air heat exchanger 12 depending for its efficiency upon the vane area and air flow rate provided by a fan 13.

The instant invention is functional and has safety measures built into it. However, if a part of the TMS system becomes impaired, which would usually result in a rapid acceleration of semiconductor 2 temperature and virtually immediate destruction of the semiconductor 2, the Thermal Management System of the preferred embodiment continues to absorb excess heat from the semiconductor 2 through the conductive process of the solid to air heat exchange afforded by the TMS frame 3 and the heat exchange vanes provided thereon. This backup action of the TMS frame 3 as an independent heat exchanger produces a slow heat buildup with ample time for alarms and system shutdown to protect the semiconductor 2. Additionally, if the failed unit is the TEC device 40, the absorption of heat by the Liquid Accumulator 31 and transfer of heated liquid out of the Liquid Accumulator 31 via the action of the pumping unit 10 to the liquid to air heat exchanger 12 will continue, albeit the efficiency of operation of the TMS will be reduced and again an alarm state should be entered notifying the system operator of the need for remedial action.

The Thermal Management Systems method is to cool a semiconductor 2 directly through a Thermoelectric Device 40 including the Thermal Management System frame 3, Liquid Accumulator 31, Liquid to Air Heat Exchanger 12, Pump 10, Tank (not depicted in the drawings) and fluid tube extensions or lines 4, 5, and 11, in a closed end loop configuration with a control card 8. The invention also provides a universal Anchor 35 attachments to the motherboard 1 around the semiconductor 2 socket to support the Thermal Management System frame 3 by screwing it directly onto the Anchors 35 which are attached to the motherboard 1.

The Anchors 35 have holes to allow screws to attach the Thermal Management System frame 3 to the motherboard I. The top cover plate 30 design that is the cover of the Thermal Management System frame 3, and has screw holes 41a-d in each corner for TMS frame 3 attachment, and to limit the amount of pounds per square inch pressure applied to the screw turns; and the pressure limits required by motherboard 1, and semiconductor 2 manufacturers to achieve required effective contact pressure. The Thermal Management System can be extracted without removing the motherboard 1. Unscrewing the TMS frame 3 from Anchor 35 attachments on the motherboard 1 permits easy, safe removal of a cooling device, including the frame 3 of the TMS, from the semiconductor 2 and motherboard 1.

The instant invention also provides an open area 37 in the embodiment's base of the TMS frame 3, and thereby allows insertion of a temperature probe 6, and the open area 37, it also allows the temperature probe 6 to reach the side of the semiconductor 2 to directly measure the semiconductor's 2 temperature. Motherboards 1 that contain semiconductor 2 socket temperature sensors to measure the airflow's temperature around the sensors and semiconductor 2 create a mean average temperature reading. This permits the instant invention to allow comparing the temperature probe's 6 results and the internal sensor measurement readings to determine temperature of the semiconductor 2.

The TMS method of controlling the temperature of semiconductors 2 and Thermoelectric Device 40 arrangements in accordance with the present invention, and, is comprised of a Thermoelectric Device 40 attached to the Thermal Management system interior frame 3 which is also designed to also allow insertion of a Liquid Accumulator 31, with its high density interior of extensions for efficient thermal heat absorption: Said Liquid Accumulator 31 has a liquid inlet fitting 18 and liquid outlet fitting 23 for transfer of liquid to a heat exchanger 12, and said exchanger 12 cools the liquid; which is then circulated back through line 11 to a liquid tank (not depicted in the drawings) and pump 10, and then back through the Liquid Accumulator 31 which is set inside the TMS frame 3 with liquid transfer to and from inlet and outlet pipes, resulting in a closed end loop design.

The instant invention also uses circulating liquid, circulated by pump 10. The flow path for cooling liquid throughout the TMS begins at the pump 10, proceeds though line 5 to the fluid inlet fitting 18 into the Liquid Accumulator 31, then proceeds out of the Liquid Accumulator 31 through the fluid outlet fitting 23 through line 4 to the Heat Exchanger 12, and finally proceeds out of the Heat Exchanger 12 through line 11 back to the input of the pump 10. Thus the fluid flow path through the TMS describes a continuous closed end loop.

The Liquid Accumulator 31 is closely attached to the Thermoelectric Device's 40 hot side, to be cooled down, and has a liquid input fitting 18 connected to a liquid input tube, line 5, and a liquid output fitting 23 connected to a liquid output tube, line 4. The liquid input tube or line 4 and the liquid output tube, line 5, are respectively connected to output and input ends of liquid pumping 10 and a heat-exchanging unit 12.

This design is functional and safe. The efficiency of the instant invention can become impaired by failure of any part of the Thermal Management System, which usually results in a rapid acceleration of semiconductor 2 temperature; and immediate destruction of the semiconductor 2. However, the Thermal Management System is designed to continue to absorb and, move temperatures away from the semiconductor 2.

If one or all parts of the Thermal Management Systems fails, the semiconductor 2 continues to operate because, the rising temperature levels from the semiconductor 2 continues to be absorbed though the Thermal Management System's, and, which includes material that dissipates the heat through the TMS frame 3.

The Thermal Management. System method for controlling Thermoelectric device 40 and semiconductor 2 temperature arrangement, and is in accordance with the present invention comprised of a Thermoelectric Device 40 attached to the Thermal Management System interior frame 3, and which is also designed to allow the insertion of a Liquid Accumulator 31, and, said Liquid Accumulator's 31 high density interior configuration of extensions for maximizing the transfer of thermal heat absorption from the Thermoelectric Device 40, and, which is cooled by the liquid flow. The Liquid Accumulator 31, which includes a liquid inlet through fitting 18 and outlet through fitting 23 for liquid transfer to a heat exchanger 12 to cool the liquid, sent back to a liquid tank (not depicted in drawings) and pump 10 and back through the Thermal Management System frame 3, in a closed end loop

The Liquid Accumulator's 31 first liquid pipe connector which is connected to one end, namely, the output fitting of the pump 10 through a liquid tube, line 5, and a liquid outlet fixedly mounted with a second liquid pipe connector, which is connected to one end namely, the input fitting of the heat exchanger 12 by a liquid tube, line 4. The other end, namely, the output fitting of the Heat exchanger 12 is connected to one end, namely, the input fitting 18 of the Liquid Accumulator 31 and the other end, namely, the output fitting 23 of the Liquid Accumulator's 31 liquid outlet pipe connector end and the other end, namely, the inlet pipe into the pump 10 by a liquid tube, line 5.

The Thermal Management System frame 3 is an additional heat dissipater configuration, and the frame 3 is made having an open area that allows the insertion of the Liquid Accumulator 31 or chamber and Thermoelectric Device 40 to the interior bottom side of the Thermal Management System frame 3. When assembled, the said Liquid Accumulator 31 is disposed in close contact with the thermoelectric Device 40 and peripheral side walls of the Thermal Management System frame 3 to dissipate heat.

The present invention has been designed to provide a Thermoelectric Device 40, a Thermal Management Systems frame 3, which includes a Liquid Accumulator 31 as part of the invention, the capability of attaching the Thermal Management System frame 3 to a motherboard 1, by screws, and, are attached to Anchors 35 on the motherboard 1 for a semiconductor 2 Device arrangement. Additionally, the present invention provides a Liquid Accumulator 31, and, Thermoelectric Device 40, and, the Thermal. Management System frame 3, and, including the capability to attach the Thermal Management Solutions method for a semiconductor 2 Device arrangement, which uses active Thermoelectric Devices 40, and the Thermal Management System frame 3 for attachment, and heat dissipation, and also, including a screw-down method to Anchor 35 the Thermal Management System frame 3 to the motherboard 1 for maximum Device efficiencies to effectively and to quickly carry heat away from the Thermoelectric Device's 40 hot side and the semiconductor 2. Finally, the present invention provides a Liquid Accumulator 31 to cool the hot side of a thermoelectric Device 40.

The present invention provides a safety design to support the operation of a semiconductor 2 if any part of the Thermal Management System fails and the Thermal Management System solution method for a Device arrangement, which keeps the semiconductor 2 functioning without destroying it: The semiconductor 2 can continue to function at safe temperature levels allowing the controller unit 8 to alert the operator of the semiconductor's 2 temperatures increasing and to turn off the electronic Device for safety of parts.

The preferred embodiment of the present invention provides a direct active Thermoelectric Device 40 for direct spot cooling of the semiconductor 2 and enhances the properties of the Thermal Management System, conducting heat away from the Thermoelectric Device 40 and semiconductor, and, that is adaptable to smaller environments requiring less installation space.

When turning on the semiconductor 2, a Thermoelectric Device 40 is activated along with the pump 10 started to pump liquid, and, causing it to circulate continuously through the liquid tubes (lines 4, 5, and 11), pump 10, and, said Liquid Accumulator 31, carrying the Thermoelectric Devices 40 heat from the hot side transferred to the liquid passing through the Liquid Accumulator 31, liquid tubes (lines 4, 5, and 11), heat exchangers, liquid tank (not depicted in the drawings) and then to the back to the entire Thermal Management Systems in a closed end liquid format. The invention provides a continuous flow of liquid passing through the heat exchanger 12, and temperatures are dissipated from liquid, and expelled to the outside, therefore, colder liquid is continuously circulated, and, higher temperatures to be carried away from the TEC and the TMS. The Heat Exchanger 12 dissipates the elevated temperatures of the liquid and blows across it into the outside air.

When starting the operation of the semiconductor 2 the Thermoelectric Device 40 immediately is activated, causing liquid to flow through the sum of the parts of the Thermal Management System, and enabling increased temperatures of the semiconductor 2 being cooled to be quickly dissipated. Residual heat that is not totally captured by the liquid Accumulator 31 is further dissipated through the frame 3 of the preferred embodiment of the TMS.

While only one embodiment of the present invention has been shown and described, it will be understood that various modifications and changes could be made thereunto without departing from the spirit and scope of the invention disclosed.

I claim:

1. A semiconductor thermal management system comprising
a fluid,
one or more thermoelectric devices,
a liquid accumulator,
a fluid to air heat exchanger, and
a pump;
wherein said thermoelectric devices are in conductive heat exchange with said semiconductor,
said thermoelectric devices are in conductive heat exchange with said liquid accumulator,
said liquid accumulator is in conductive heat exchange with said fluid,
said liquid accumulator is in fluid communication with said fluid to air heat exchanger,
said fluid to air heat exchanger is in fluid communication with said pump, and said pump is in fluid communication with said liquid accumulator,
whereby said semiconductor expells heat into said fluid in said liquid accumulator,
said fluid expells heat into the air in said fluid to air heat exchanger,
said pump causes said fluid to circulate within said system, and
said semiconductor is cooled.
